(19) United States
(12) Patent Application Publication
(10) Pub. No.: US 2003/0095447 A1
(43) Pub. Date: May 22, 2003

(54) Shared memory controller for display processor

(75) Inventor: John E. Dean, Stormville, NY (US)

Correspondence Address: Philips Electronics North America Corporation, 580 White Plains Rd., Tarrytown, NY, 10591-5190, US

(73) Assignee: Koninklijke Philips Electronics N.V.

(21) Appl. No.: 10/214,930

(22) Filed: Aug. 8, 2002

Related U.S. Application Data
(60) Provisional application No. 60/331,916, filed on Nov. 20, 2001.

(51) Int. Cl. G11C 7/00

(52) U.S. Cl. 365/200

(57) ABSTRACT

A system and method for controlling video data being communicated between a shared memory device and a plurality of process queues via a bi-directional bus. The system comprises a row address generator for associating a row address with each process queue; a system for determining a fullness of each process queue; a scheduling system for selecting a process queue to communicate with the shared memory device based on the determined fullness of each process queue; and a controller for causing the shared memory device to communicate with the selected process queue and for causing video data to be burst between the shared memory device and the selected process queue.

### CROSS-REFERENCE TO RELATED APPLICATION

This application claims the benefit of copending provisional application No. 60/331,916 filed on Nov. 20, 2001.

### FIELD OF TECHNOLOGY

The present invention relates generally to shared memory controllers, and more specifically relates to a system and method for controlling real-time video data being written to and read from a shared memory via a plurality of memory queues prior to being sent to a display device.

### BACKGROUND AND SUMMARY

As the demand for devices having feature-rich video displays, such as laptops, cell phones, personal digital assistants, flat screen TV's, etc., continues to increase, the need for systems that can efficiently process video data has also increased. One of the challenges involves managing the flow of video data from a video source to a video display. Specifically, systems may be required to handle multiple real-time processes.

Microprocessor and graphics processing systems often utilize a shared memory system in which multiple processes must access a shared memory device (e.g., bus, memory chip, etc.). In these cases, each process must compete for the shared memory system and potentially include some means for temporarily storing information until the process is granted access to the memory. To facilitate this process, memory controllers for a shared memory interface are utilized. Present day systems address competing processes that typically include high bandwidth, non-real-time processes (e.g., CPU instructions), low bandwidth processes, etc. These systems typically use priority schemes, tokens, or other means to arbitrate competing processes. For instance, U.S. Pat. No. 6,247,084, issued to Apostol et al., specifies a shared memory controller that arbitrates for a system that includes only a single real-time process. U.S. Pat. No. 6,189,064, issued to MacInnis et al., describes a shared memory system for a set-top-box that includes multiple real-time processes, but requires block out timers to enforce a minimal interval between process accesses, which limits the effectiveness of the system.

Unfortunately, prior art systems fail to provide an efficient solution for controlling multiple real-time processes, such as those required in video processing systems. Accordingly, a need exists for an efficient system to arbitrate between multiple real-time processes in a video processing system.

The present invention addresses one or more of the above-mention problems, by providing a system and method for controlling video data being communicated between a shared memory device and a plurality of process queues via a bi-directional bus. In a first aspect, the invention provides a circuit for processing video data for a display processor, comprising: a shared memory device; a plurality of process queues coupled to the shared memory device for temporarily storing video data, wherein each process queue includes a system for determining a fullness of the process queue; and a memory control system that examines the fullness of each process queue and schedules data bursts between the process queues and the shared memory device.

In a second aspect, the invention provides a method of controlling video data being communicated between a shared memory device and a plurality of process queues via a bi-directional bus, comprising: associating a row address with each process queue; determining a fullness of each process queue; arbitrating among the process queues to select a process queue having a highest priority based on the determined fullness of each process queue; controlling the shared memory device to communicate with the selected process queue; and bursting video data between the shared memory device and the selected process queue.

In a third aspect, the invention provides a system for controlling video data being communicated between a shared memory device and a plurality of process queues via a bi-directional bus, comprising: a row address generator for associating a row address with each process queue; a system for determining a fullness of each process queue; a scheduling system for selecting a process queue to communicate with the shared memory device based on the determined fullness of each process queue; and a controller for causing the shared memory device to communicate with the selected process queue and for causing video data to be burst between the shared memory device and the selected process queue.

### BRIEF DESCRIPTION OF THE DRAWING FIGURES

These and other features of this invention will be more readily understood from the following detailed description of the various aspects of the invention taken in conjunction with the accompanying drawings in which:

FIG. 1 depicts an exemplary video processing circuit in accordance with the present invention.

FIG. 2 depicts a memory control system for a display processor in accordance with the present invention.

### DETAILED DESCRIPTION

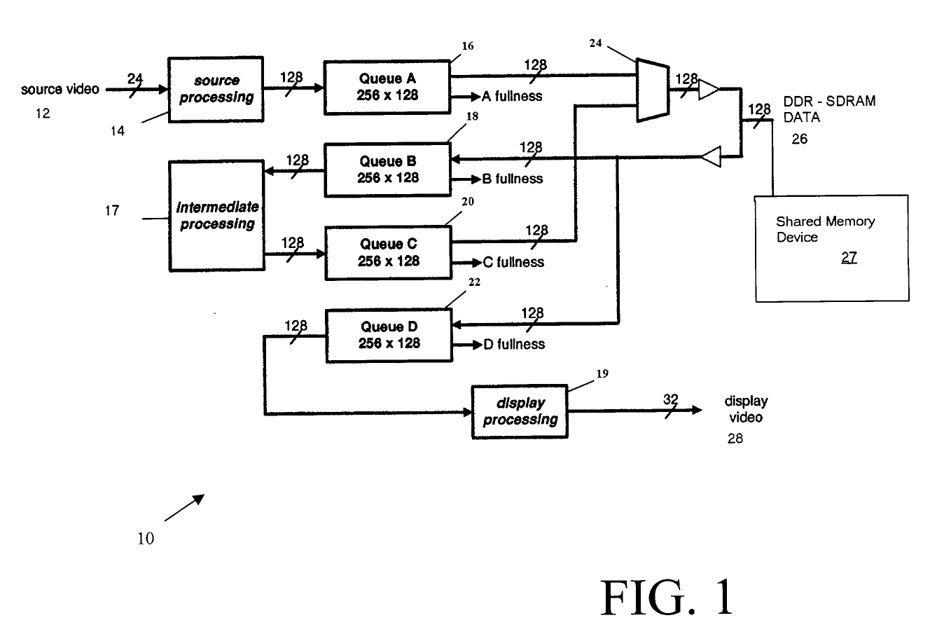

Referring now to the drawings, FIG. 1 depicts an exemplary video data processing circuit 10 for processing video data being sent to a video display. In this embodiment, processing circuit 10 receives source video 12, processes the video at different points along the circuit, and outputs display video 28. Source video 12 is inputted into processing circuit 10 via a 24-bit bus, and is outputted via a 32-bit bus. All other communications within circuit 10 occur via a 128-bit bus (selection of which is described below). Video processing is handled by a source processing system 14, an intermediate processing system 17, and a display processing system 19. Processing circuit 10 also includes a shared memory device 27 that is accessible via the 128-bit bus. Shared memory device 27 may be utilized to, for instance, provide a frame delay mechanism at two points in processing circuit 10 and may include, for example, a 128-bit wide bus connected to a bank of double data rate synchronous dynamic random access memory (DDR-SDRAM). Other large shared memory systems, such as SGRAM, SDRAM, RAMBUS, etc., could likewise be utilized.

Processing circuit 10 further includes four process queues 16, 18, 20, 22, that vie for access to the shared memory device 27. Each process queue temporarily stores data that is being written to or read from shared memory device 27, and may be implemented using a first-in first-out architecture (FIFO) that stores data in a 256×128 bit dual port static RAM (SRAM) memory implemented as a synchronous FIFO. The right side of each of the four process queues is preferably clocked at the same rate as the shared memory device (e.g., 200 MHz), and should therefore utilize the same 128-bit wide bus as the shared memory. In order to handle large data transfers necessary for a video application, data, shown as DDR-SDRAM data 26, is “burst” between the process queues 16, 18, 20, 22 and the shared memory device 27. A typical size of each data burst may range from 10 to 80 consecutive 128-bit words. The left side of each process queue may be clocked at a different rate (e.g., lower) than the shared memory clock. However, the average bandwidth into and out of each queue must be the same to prevent underflow or overflow.

It is understood that process circuit 10 is shown for exemplary purposes only, and other configurations of video processing circuits in which multiple real-time processes compete for a shared memory device are within the scope of the invention. Regardless of the specific configuration, one of the challenges of such a circuit is how to arbitrate among the process queues to determine which process queue should have access to the shared memory device 27. The present invention addresses this by providing a system for measuring a fullness of each process queue. In one exemplary embodiment, fullness is measured as the number of unread words in the memory of the process queue. However, any method for measuring the amount of data stored in a memory device could be utilized. Based on the fullness of each process queue 16, 18, 20, 22, a determination of when each process queue is ready to send or receive a burst of data can be made.

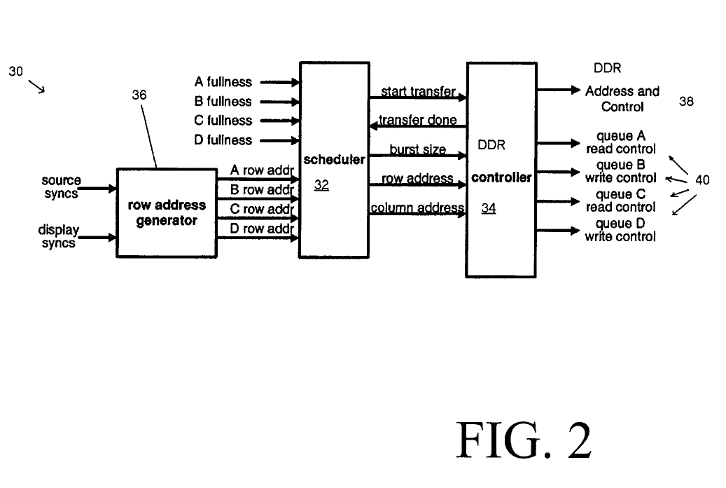

Referring now to FIG. 2, a memory control system 30 is provided for controlling access to and from the shared memory device 27. Memory control system 30 continuously monitors the fullness measure of each process queue to arbitrate and grant access to a select one of the four process queues. Memory control system 30 includes a row address generator 36, a scheduler 32, and a controller 34. Row address generator 36 calculates row addresses for each of the four process queues 16, 18, 20, 22 based on source and display sync signals. Scheduler 32 monitors the fullness of the four process queues and determines if one or more of the process queues requires access. If access is required, the scheduler 32 selects a process queue to access the shared memory device by issuing the necessary commands to controller 34. The commands may include a start signal, a burst size of the data to be communicated, a row address, and a column address. Based on these commands, controller 34 generates all of the necessary timing signals to execute the burst. Specifically, controller 34 issues address and control information 38 to the shared memory device 27, and issues a read or write control signal 40 to the appropriate process queue.

The scheduler 32 arbitrates the process queues by comparing the fullness of each process queue to a predetermined threshold for each process queue. The threshold value may be different for each process queue, and may be based on the size of the memory, the size of the burst, and the line timing (which may differ for each process queue). As can be seen in FIG. 1, there are two process queues (queue A 16 and queue C 20) that hold data for writing to shared memory device 27, and two process queues (queue B 18 and queue D 22) that hold data being read from shared memory device 27. For process queues (e.g., A & C) that are holding data to write, the fullness must be greater than the threshold to trigger a burst of data to send. For process queues (e.g., B & D) that are reading data, the fullness must be less than the threshold to trigger a burst of data to receive. Accordingly, scheduler 32 can determine that one or more process queues need access whenever a respective threshold is crossed.

After each burst, scheduler 32 checks the fullness of each process queue to see if another burst is required. If two or more process queues require access at the same time (e.g., both have a fullness measure that crossed the threshold), then the one that has been waiting the longest is selected. If two or more process queues have been waiting the same amount of time (i.e., they crossed the threshold at the same clock cycle), then the one with the highest bandwidth requirement is selected. In one exemplary embodiment, no process queue should hold the bus for more than one burst at a time when others are waiting, and all bursts that are started should be completed. Moreover, none of the process queues should be allowed to overflow or underflow. However, the write process queues (A & C of FIG. 1) should be allowed to become empty (e.g., during vertical blanking). The read process queues (B & D of FIG. 1) should not be allowed to become empty.

As noted above, this exemplary embodiment utilizes a 128-bit bus. The bus width should be selected based on a worst-case bandwidth situation for the particular circuit. In the circuit of FIG. 1, if the process B rate is double the process A rate and equal to the process C rate, and the process D rate is triple the process C rate, then the worst case bandwidth requirement (BW) of the shared memory data bus can be calculated as:

BW=write rate A+read rate B+write rate C+read rate D+overhead;

BW=write rate A+(2*write rate A)+(2*write rate A)+(6*write rate A)+overhead;

BW=(11*write rate A)+overhead;

Then, for example, if the peak input rate is 75 MHz@24 bits/pixel (typical for HDTV) and the overhead is 15%, then BW=11*75,000,000*24*1.15=22,770,000,000 bits/sec. Assuming a 200 MHz memory clock rate, the memory bus width must be a minimum of BW/200,000,000=114 bits wide. For practical reasons, a bus width of 128 is selected for this application. However, it should be understood that for other, less complex applications, a smaller bus width (e.g., 32 bits) may suffice.

The size (i.e., depth) of the memory devices in each process queue 16, 18, 20, 22 may depend on several factors, including burst size and horizontal sync (line) timing. In general, the memory depths should be minimized to reduce costs. However, to reduce overhead in the memory bus, large burst sizes are desirable, which require deeper memory. Accordingly, a compromise is required. Moreover, the line timing parameters for each process are not necessarily the same. For example, source video 12 (stored in process queue A 16) may have large blanking intervals between lines giving a larger peak bandwidth than the data required to be stored in process queue B 18. Due to these conflicting requirements, memory depth may be determined with behavioral simulations over a range of parameter settings.

The foregoing description of the preferred embodiments of the invention has been presented for purposes of illustration and description. They are not intended to be exhaustive or to limit the invention to the precise form disclosed, and obviously many modifications and variations are possible in light of the above teachings. Such modifications and variations that are apparent to a person skilled in the art are intended to be included within the scope of this invention as defined by the accompanying claims.

I claim:

1. A circuit for processing video data for a display processor, comprising:
a shared memory device;
a plurality of process queues coupled to the shared memory device for temporarily storing video data, wherein each process queue includes a system for determining a fullness of the process queue; and
a memory control system that examines the fullness of each process queue and schedules data bursts between the process queues and the shared memory device.

2. The circuit of claim 1, wherein the shared memory device comprises a double data-rate synchronous dynamic random access memory (DDR-SDRAM).

3. The circuit of claim 2, wherein each process queue comprises a first-in first-out implemented as a synchronous FIFO.

4. The circuit of claim 3, wherein a first process queue is configure to receive a first burst of video data from the shared memory device, and a second process queue is configured to send a second burst of video data to the shared memory device.

5. The circuit of claim 3, wherein a first and second process queue are configure to receive bursts of video data from the shared memory device, and a third and fourth process queue are configured to send bursts of video data to the shared memory device.

6. The circuit of claim 5, wherein each process queue is coupled to the DDR-SDRAM is via a bi-directional bus having a range of 32 to 128 bits.

7. The circuit of claim 6, wherein each burst of video data comprises at least 10 consecutive 128-bit words.

8. The circuit of claim 1, wherein the memory control system comprises:
a scheduler that receives a fullness measure from each process queue; prioritizes the process queues based on each of the received fullness measures, and outputs a selected process queue; and
a controller for causing the shared memory device to communicate with a selected process queue.

9. The circuit of claim 8, wherein the memory control system further comprises a row address generator for transmitting a row address for each process queue to the scheduler.

10. The circuit of claim 8, wherein the scheduler outputs a row address, column address and burst size to the controller.

11. A method of controlling video data being communicated between a shared memory device and a plurality of process queues via a bi-directional bus, comprising:
associating a row address with each process queue;
determining a fullness of each process queue;
arbitrating among the process queues to select a process queue having a highest priority based on the determined fullness of each process queue;
controlling the shared memory device to communicate with the selected process queue; and
bursting video data between the shared memory device and the selected process queue.

12. The method of claim 11, wherein the fullness of each process queue is determined by calculating a number of unread words in the process queue.

13. The method of claim 11, wherein step of arbitrating among the process queues includes the step of comparing the fullness of each process queue to a predetermined threshold value for each process queue.

14. The method of claim 13, wherein the predetermined threshold value is based on the memory size of the process queue and the burst size of the data being communicated.

15. The method of claim 11, wherein step of arbitrating among the process queues includes the steps of:
giving priority to the process queue that has been waiting the longest; and
for process queues that have been waiting for the same period time, giving priority to the one having the highest bandwidth requirement.

16. The method of claim 11, wherein the controlling step includes:
providing a signal to the selected process queue to cause it to read data from the bus or write data to the bus;
providing an address and control signal to the shared memory device to cause it to write or read data to or from the provided address.

17. A system for controlling video data being communicated between a shared memory device and a plurality of process queues via a bi-directional bus, comprising:
a row address generator for associating a row address with each process queue;
a system for determining a fullness of each process queue;
a scheduling system for selecting a process queue to communicate with the shared memory device based on the determined fullness of each process queue; and
a controller for causing the shared memory device to communicate with the selected process queue and for causing video data to be burst between the shared memory device and the selected process queue.

18. The system of claim 17, wherein the one selected process queue is configured to receive a burst of data from the shared memory device.

19. The system of claim 17, wherein the one selected process queue is configured to send a burst of data to the shared memory device.

20. The system of claim 17, wherein the bi-directional bus comprises between 32 and 128 bits.
